(19) United States
(12) Patent Application Publication
(10) Pub. No.: US 2009/0066388 A1
(43) Pub. Date: Mar. 12, 2009

(54) Schmitt Trigger Circuit

(76) Inventor: Sung Jin Park, Bucheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/200,978

(22) Filed: Aug. 29, 2008

(30) Foreign Application Priority Data
Sep. 6, 2007 (KR) 10-2007-0090292

(51) Int. Cl. H03K 3/00

(52) U.S. Cl. 327/206

(57) ABSTRACT

A Schmitt trigger circuit having at least eight transistors is provided. The first transistor can have a source connected to a power terminal, and the second transistor can have a source connected to a drain of the first transistor. The third transistor can have a source connected to the drain of the first transistor, and the fourth transistor can have a source connected to a drain of the third transistor and a drain electrically connected to a ground terminal. The fifth transistor can have a drain connected to a drain of the second transistor, gates of the third and fourth transistors, and an output terminal. The sixth transistor can have a drain connected to a source of the fifth transistor and a source connected to the ground terminal. The seventh transistor can have a source connected to the source of the fifth transistor and a gate connected to the output terminal. The eighth transistor can have a source connected to a drain of the seventh transistor, a gate connected to the output terminal, and a drain electrically connected to the power terminal.

### CROSS-REFERENCE TO RELATED APPLICATION

The present application claims the benefit under 35 U.S.C. §119 of Korean Patent Application No. 10-2007-0090292, filed Sep. 6, 2007, which is hereby incorporated by reference in its entirety.

### BACKGROUND

In general, a Schmitt trigger circuit operates such that the voltage of the output signal is kept at a high level until the potential level of the input signal reaches a reference voltage. When the potential level of the input signal becomes larger than the reference voltage, the voltage of the output signal of the circuit changes from a high level to a low level. The voltage is maintained at a low level until the potential level of the input signal is reduced to the reference voltage. When the potential level of the input signal falls below the reference voltage, the voltage of the output signal changes from a low level to a high level.

Accordingly, a Schmitt trigger circuit can be thought of as an amplitude modulation circuit. The Schmitt trigger circuit can maintain its output signal at a constant voltage level, even though the input voltage changes. The Schmitt trigger circuit can be used for stable operation of a semiconductor device, as well as many other purposes in various electronic circuits.

FIG. 1 is a schematic circuit diagram showing a Schmitt trigger circuit 10 including six transistors.

Referring to FIG. 1, the upper three transistors, that is, the first, second, and third transistors, 11, 12, and 13, are p-channel metal oxide semiconductor (PMOS) transistors; and the lower three transistors, that is, the fourth, fifth, and sixth transistors 14, 15, and 16, are n-channel metal oxide semiconductor (NMOS) transistors.

In general, the source of the first transistor 11 is connected to a power terminal DVDD, and the drain of the first transistor 11 is connected to the source of the second transistor 12 and the source of the third transistor 13.

The drain of the third transistor 13 is typically connected to the ground terminal DVSS.

Additionally, the drain of the second transistor 12 is connected to the drain of the fourth transistor 14, the gate of the third transistor 13, the gate of the sixth transistor 16, and an output terminal OUT. The source of the fourth transistor 14 is connected to the drain of the fifth transistor 15 and the source of the sixth transistor 16.

The source of the fifth transistor 15 is generally connected to the ground terminal DVSS, and the drain of the sixth transistor 16 is connected to the power terminal DVDD. The gates of the first transistor 11, the second transistor 12, the fourth transistor 14, and the fifth transistor 15 are each connected to an input terminal IN.

Thus, if a signal input to the input terminal IN has a low potential level, the first and second transistors 11 and 12 are typically turned on, and the fourth and fifth transistors 14 and 15 are turned off.

Therefore, a power voltage of the power terminal DVDD can be applied to the first and second transistors 11 and 12 such that the potential level of the output terminal OUT becomes high. Also, the power voltage can be applied to the gate of the sixth transistor 16 to turn on the sixth transistor 16.

When the sixth transistor 16 is on, the power voltage is applied to the source of the fourth transistor 14 and the drain of the fifth transistor 15. Thus, the source and drain of the fourth transistor 14 can be at the same potential level, so that the output terminal OUT can retain its high potential level even if the potential level of the input signal to the input terminal IN increases.

Additionally, if a signal input to the input terminal IN has a high potential level, the first and second transistors 11 and 12 are typically turned off, and the fourth and fifth transistors are turned on. Therefore, the output terminal OUT is connected to the ground terminal DVSS through the fourth and the fifth transistors 14 and 15 such that the potential level of the output terminal OUT becomes low.

At this time, a low voltage is applied to the gate of the third transistor 13 such that the third transistor 13 is turned on and the power voltage of the power terminal DVDD is applied to the ground terminal DVSS through the third transistor 13.

As a result, the source and drain of the second transistor 12 can be at the same potential level so that the output terminal OUT can retain its low potential level even if the potential level of the signal input to the input terminal IN decreases.

The reference voltage, which determines whether the output signal of the Schmitt trigger circuit 10 changes, typically does not have a fixed value but a predetermined range of values.

Since the reference voltage has a predetermined range of possible values, a delay generally occurs for a transition time interval. In other words, after the voltage of the input signal reaches the reference voltage and a predetermined time passes, then the voltage of the output signal changes.

The transition time interval is determined by a ratio of capacitances of the transistors in the circuit, which can make circuit design difficult.

Furthermore, there is a limit on how much the transition time interval can be increased. Thus, the Schmitt trigger circuit can be strongly affected even by small amounts of noise, and the operation of the Schmitt trigger circuit can be unstable.

### BRIEF SUMMARY

Embodiments of the present invention provide a Schmitt trigger circuit capable of having an extended transition time interval for increasing or decreasing the voltage of an output signal. Therefore, the effect of noise on the Schmitt trigger circuit can be inhibited, and the circuit can operate more rapidly and efficiently.

In one embodiment, a Schmitt trigger circuit can comprise: a first transistor comprising a source connected to a power terminal; a second transistor comprising a source connected to a drain of the first transistor; a third transistor comprising a source connected to the drain of the first transistor; a fourth transistor comprising a source connected to a drain of the third transistor, a gate connected to an output terminal and a drain electrically connected to a ground terminal; a fifth transistor comprising a drain connected to a drain of the second transistor, a gate of the third transistor, the gate of the fourth transistor, and the output terminal; a sixth transistor comprising a drain connected to a source of the fifth transistor and a source connected to the ground terminal; a seventh transistor comprising a source connected to the source of the fifth transistor and a gate connected to the output terminal; and an eighth transistor comprising a source connected to a drain of the seventh transistor, a gate connected to the output terminal, and a drain electrically connected to the power terminal.

In another embodiment, a Schmitt trigger circuit can comprise: a first transistor comprising a source connected to a power terminal; a second transistor comprising a source connected to a drain of the first transistor; a third transistor comprising a source connected to the drain of the first transistor; a plurality of fourth transistors in series, wherein an initial transistor of the plurality of fourth transistors comprises a source connected to a drain of the third transistor, and wherein a last transistor of the plurality of fourth transistors comprises a drain connected to a ground terminal, and wherein each of the fourth transistors except the last transistor of the fourth transistors comprises a drain connected to a source of an adjacent fourth transistor, and wherein each transistor of the fourth transistors comprises a gate connected to an output terminal; a fifth transistor comprising a drain connected to a drain of the second transistor, a gate of the third transistor, the gate of each of the fourth transistors, and the output terminal; a sixth transistor comprising a drain connected to a source of the fifth transistor and a source connected to the ground terminal; a seventh transistor comprising a source connected to the source of the fifth transistor and a gate connected to the output terminal; and a plurality of eighth transistors in series, wherein an initial transistor of the plurality of eighth transistors comprises a source connected to a drain of the seventh transistor, and wherein a last transistor of the plurality of eighth transistors comprises a drain connected to the power terminal, and wherein each of the eighth transistors except the last transistor of the eighth transistors comprises a drain connected to a source of an adjacent eighth transistor, and wherein each transistor of the eighth transistors comprises a gate connected to the output terminal.

The details of one or more embodiments are set forth in the accompanying drawings and the description below. Other features will be apparent to one skilled in the art from the detailed description, the drawings, and the claims.

### BRIEF DESCRIPTION OF THE DRAWINGS

FIG. 1 is a schematic circuit diagram showing a Schmitt trigger circuit.

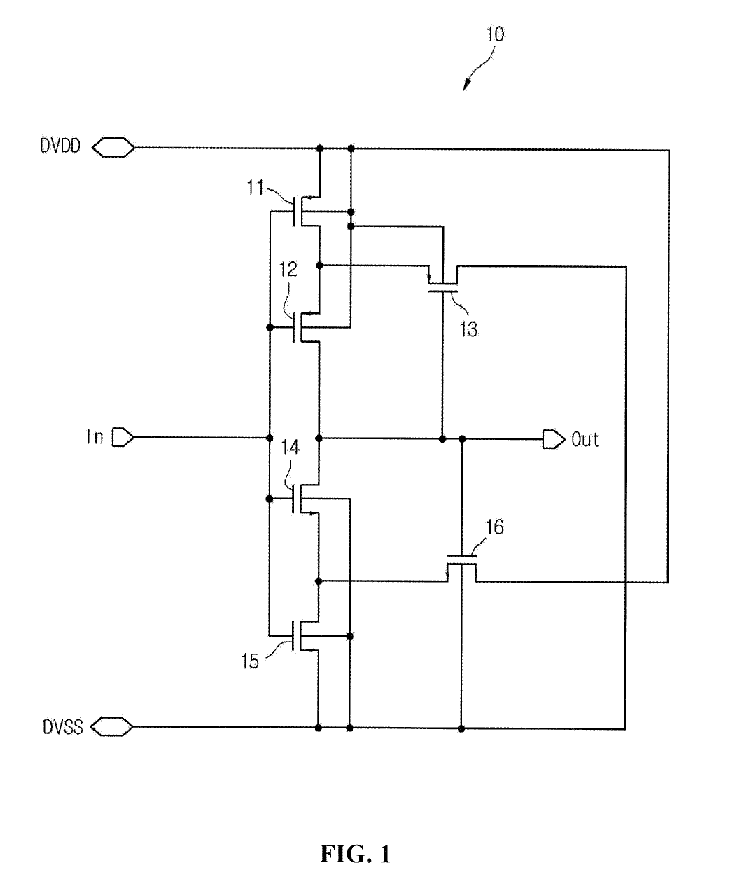

FIG. 2 is a schematic circuit diagram showing a Schmitt trigger circuit according to an embodiment of the present invention.

FIG. 3 is a graph showing voltage levels of input and output signals of a Schmitt trigger circuit according to an embodiment of the present invention.

### DETAILED DESCRIPTION

Schmitt trigger circuits according to the present invention will now be described in detail with reference to the accompanying drawings, in which embodiments of the present disclosure are shown.

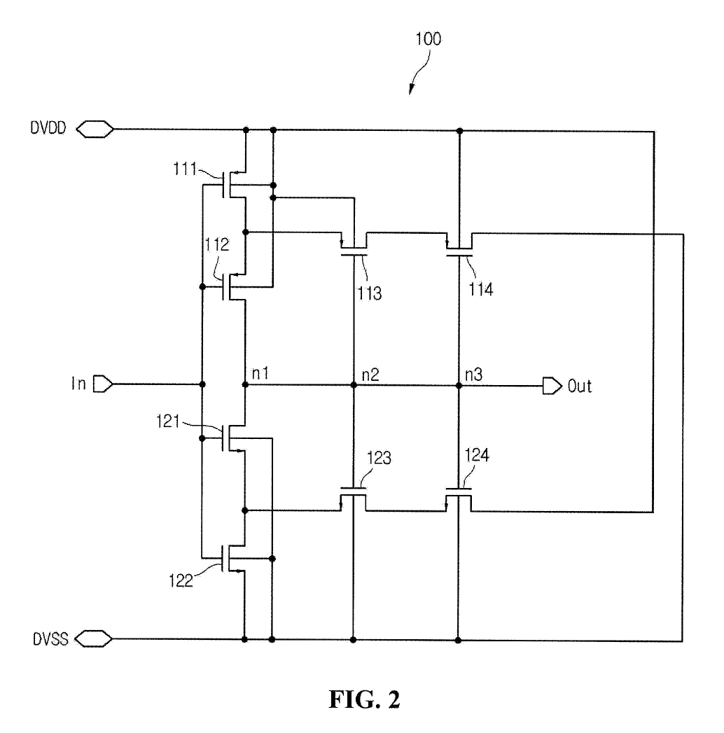

FIG. 2 is a schematic circuit diagram showing a Schmitt trigger circuit 100 according to an embodiment of the present invention.

Referring to FIG. 2, in one embodiment, a Schmitt trigger circuit 100 can include eight transistors. The upper four transistors, the first transistor 111, the second transistor 112, the third transistor 113, and the fourth transistor 114, can be p-channel metal oxide semiconductor (PMOS) transistors. The lower four transistors, the fifth transistor 121, the sixth transistor 122, the seventh transistor 123, and the eighth transistor 124, can be n-channel metal oxide semiconductor (NMOS) transistors.

In an embodiment, the source of the first transistor 111 can be connected to a power terminal DVDD, and the drain of the first transistor 111 can be connected to the source of the second transistor 112 and to the source of the third transistor 113.

The drain of the third transistor 113 can be connected to the source of the fourth transistor 114, and the drain of the fourth transistor 114 can be connected to a ground terminal DVSS.

The drain of the second transistor 112 can be connected to the drain of the fifth transistor 121 and can also be connected to the gate of the third transistor 113, the gate of the fourth transistor 114, the gate of the seventh transistor 123, and the gate of the eighth transistor 124.

Hereinafter, a node between the second transistor 112 and the fifth transistor 115 will be referred to as a first node n1; a node between the first node n1, the third transistor 113, and the seventh transistor 123 will be referred to as a second node n2; and a node between the fourth transistor 114, the eighth transistor 124, the second node n2, and an output terminal OUT will be referred to as a third node n3.

The source of the fifth transistor 121 can be connected to the drain of the sixth transistor 122 and to the source of the seventh transistor 123. The source of the sixth transistor 122 can be connected to the ground terminal DVSS.

In addition, the drain of the seventh transistor 123 can be connected to the source of the eighth transistor 124, and the drain of the eighth transistor 124 can be connected to the power terminal DVDD.

The gate of the first transistor 111, the gate of the second transistor 112, the gate of the fifth transistor 121, and the gate of the sixth transistor 122 can all be connected to an input terminal IN.

Operation of a Schmitt trigger circuit 100 will now be described according to an embodiment of the present invention.

If the potential level of a signal input to the input terminal IN is low, the first transistor 111 and the second transistor 112 can be turned on, and the fifth transistor 121 and the sixth transistor 122 can be turned off.

Accordingly, a power voltage of the power terminal DVDD can be applied through the first transistor 111 and the second transistor 112 to make the potential level of the output terminal OUT high. The power voltage making the output terminal OUT high is also applied to the gate of the seventh transistor 123 and the gate of the eighth transistor 124 from nodes n2 and n3 through the first transistor 111 and the second transistor 112.

When the power voltage is applied to the gate of the seventh transistor 123 and the gate of the eighth transistor 124, the seventh transistor 123 and the eighth transistor 124 can be turned on so that the power voltage can be applied to the source of the fifth transistor 121 and the drain of the sixth transistor 122 through the seventh and eighth transistors 123 and 124.

At this time, the source and drain of the fifth transistor 121 can be at the same potential level because of the power voltage applied to the source of the fifth transistor 121 through the seventh and eighth transistors 123 and 124, and the power voltage applied to the drain of the fifth transistor 121 through the first and second transistors 111 and 112. Therefore, the output terminal OUT can retain its high potential level even if the potential level of the input signal to the input terminal IN increases.

Here, the voltage between the gate and the source of the fifth transistor 121 can be represented by Equation 1 below.

V_{GS5}=V_{In}−(V_{DVDD}−V_{TH7}−V_{TH8})=V_{In}+V_{TH7}+V_{TH8}−V_{DVDD} [Equation 1]

V_{GS5} denotes the voltage between the gate and the source of the fifth transistor 121, V_{In} denotes the voltage of the input signal, V_{DVDD} denotes the power voltage, V_{TH7} denotes the threshold voltage of the seventh transistor 123, and V_{TH8} denotes the threshold voltage of the eighth transistor 124. In an embodiment, the lower NMOS transistors can all have the same threshold voltage, such that the seventh transistor 123 can have the same threshold voltage as the eighth transistor 124. In this embodiment, (V_{TH7}+V_{TH8}) can be simplified as 2V_{THn}, where V_{THn} is the threshold voltage of each of the NMOS transistors.

Thus, it can be seen that the voltage between the gate and source of the fifth transistor 121 can be increased with a larger threshold voltage of the seventh transistor 123 and the eighth transistor 124.

If the potential level of a signal input to the input terminal IN is high, the first transistor 111 and the second transistor 112 can be turned off, and the fifth transistor 121 and the sixth transistor 122 can be turned on.

Therefore, the output terminal OUT can be electrically connected to the ground terminal DVSS through the fifth transistor 121 and the sixth transistor 122, and thus the potential level of the output terminal OUT can become low.

At this time, a low voltage can be applied to the gate of the third transistor 113 and the gate of the fourth transistor 114 through nodes n2 and n3 so that the third transistor 113 and the fourth transistor 114 can be turned on.

Accordingly, the ground voltage of the ground terminal DVSS can be applied to the source of the second transistor 112 and the drain of the first transistor 111 through the third transistor 113 and the fourth transistor 114.

As a result, the source and drain of the second transistor 112 can be at the same potential level because of the ground voltage applied to the source of the second transistor 112 through the third and fourth transistors 113 and 114 and the ground voltage applied to the drain of the second transistor 112 through the fifth and sixth transistors 121 and 122. Therefore, the output terminal OUT can retain its low potential level even if the potential level of the input signal to the input terminal IN decreases.

Here, the voltage between the gate and source of the second transistor 112 can be represented by Equation 2 below.

V_{GS2}=V_{In}−|(V_{TH3}+V_{TH4})| [Equation 2]

V_{GS2} denotes the voltage between the gate and the source of the second transistor 112, V_{In} denotes the voltage of the input signal, V_{TH3} denotes the threshold voltage of the third transistor 113, and V_{TH4} denotes the threshold voltage of the fourth transistor 114. In an embodiment, the upper PMOS transistors can all have the same threshold voltage, such that the third transistor 113 can have the same threshold voltage as the fourth transistor 114. In this embodiment, (V_{TH3}+V_{TH4}) can be simplified as 2V_{THp}, where V_{THp} is the threshold voltage of each of the PMOS transistors.

Thus, it can be seen that the voltage between the gate and source of the second transistor 112 can be decreased as the threshold voltage of the third transistor 113 and the fourth transistor 114 is increased.

Though an embodiment has been depicted with a single transistor for the fourth transistor 114 and a single transistor for the eighth transistor 124, embodiments of the present invention are not limited thereto.

In an embodiment, a plurality of transistors can be provided in place of the fourth transistor 114. In this case, each of the gates of the plurality of transistors provided in place of the fourth transistor 114 can be connected to the output terminal OUT. Additionally, the source of the first transistor of the plurality of fourth transistors 114 can be connected to the drain of the third transistor 113, and the drain of each transistor of the plurality of fourth transistors 114 can be connected to the source of the next transistor of the plurality of fourth transistors 114. The drain of the last transistor of the plurality of fourth transistors 114 can be connected to the ground terminal DVSS.

In embodiments where a plurality of fourth transistors 114 are connected in series between the third transistor 113 and the ground terminal DVSS, the threshold voltage of the second transistor 112 can be adjusted. For example, the threshold voltage of the second transistor 112 can be increased by increasing the number of transistors in the plurality of fourth transistors 114.

In an embodiment, a plurality of transistors can be provided in place of the eighth transistor 124. In this case, each of the gates of the plurality of transistors provided in place of the eighth transistor 124 can be connected to the output terminal OUT. Additionally, the source of the first transistor of the plurality of eighth transistors 124 can be connected to the drain of the seventh transistor 123, and the drain of each transistor of the plurality of eighth transistors 124 can be connected to the source of the next transistor of the plurality of eighth transistors 124. The drain of the last transistor of the plurality of eighth transistors 124 can be connected to the power terminal DVDD.

In embodiments where a plurality of eighth transistors 124 are connected in series between the seventh transistor 123 and the power terminal DVDD, the threshold voltage of the seventh transistor 123 can be adjusted. For example, the threshold voltage of the seventh transistor 123 can be decreased by increasing the number of transistors in the plurality of eighth transistors 124.

In a further embodiment, a plurality of fourth transistors 114 and a plurality of eighth transistors 124 can be provided. The plurality of fourth transistors 114 and the plurality of eighth transistors 124 can each be provided as described above.

Referring again to Equation 1, the gate-to-source voltage of the fifth transistor 121, which can be directly related to the operation of stably retaining a high-potential-level output signal, can be increased. Also, referring again to Equation 2, the gate-to-source voltage of the second transistor 112, which can be directly related to the operation of stably retaining a low-potential-level output signal, can be decreased.

Accordingly, there can be a relatively large difference between a reference voltage at which the output signal can change from a high potential level to a low potential level and a reference voltage at which the output signal can change from a low potential level to a high potential level. Thus, the transition time interval of the circuit can be increased.

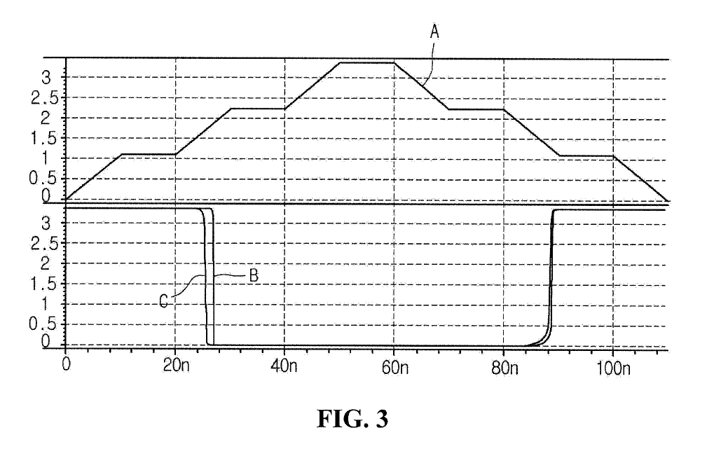

FIG. 3 is a graph showing detected input and output signals of a Schmitt trigger circuit according to an embodiment of the present invention.

Referring to FIG. 3, the x-axis and y-axis denote time and voltage, respectively, and two detected signals are shown.

The upper curve represents the voltage level of an input signal A, and the lower curves represent the voltage levels of output signals B and C.

When the voltage level of the input signal A gradually increases, the output signals B and C of the Schmitt trigger circuit change from a high potential level to a low potential level at an input signal of about 1.5 V. Also, when the voltage level of the input signal A gradually decreases, the output signals B and C of the Schmitt trigger circuit change from a low potential level to a high potential level at an input signal of about 1.5 V

Furthermore, the reference voltage for maintaining a high potential level output signal B can be increased, and the reference voltage for maintaining a low potential level output signal C can be decreased, so that the transition time interval for changing signal potential levels can be increased.

According to embodiments of the present invention, since the transition time interval for increasing or decreasing the potential level of the output signal can be increased, the effect of noise on the Schmitt trigger circuit can be inhibited and the circuit can operate more reliably.

Additionally, the transition time of the Schmitt trigger circuit can be less dependent on the capacitances of the transistors in the circuit. Thus, the Schmitt trigger circuit can be designed more easily.

Furthermore, a Schmitt trigger circuit according to embodiments of the present invention can be operated more rapidly.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A Schmitt trigger circuit, comprising:
a first transistor comprising a source connected to a power terminal;
a second transistor comprising a source connected to a drain of the first transistor;
a third transistor comprising a source connected to the drain of the first transistor;
a fourth transistor comprising a source connected to a drain of the third transistor, a gate connected to an output terminal and a drain electrically connected to a ground terminal;
a fifth transistor comprising a drain connected to a drain of the second transistor, a gate of the third transistor, the gate of the fourth transistor, and the output terminal;
a sixth transistor comprising a drain connected to a source of the fifth transistor and a source connected to the ground terminal;
a seventh transistor comprising a source connected to the source of the fifth transistor and a gate connected to the output terminal; and
an eighth transistor comprising a source connected to a drain of the seventh transistor, a gate connected to the output terminal, and a drain electrically connected to the power terminal.

2. The Schmitt trigger circuit according to claim 1, wherein a gate of the first transistor, a gate of the second transistor, a gate of the fifth transistor, and a gate of the sixth transistor are each connected to an input terminal.

3. The Schmitt trigger circuit according to claim 2, wherein, when a signal having a potential level below a reference voltage of the Schmitt trigger circuit is input to the input terminal:
the first transistor is turned on, the second transistor is turned on, the fifth transistor is turned off, and the sixth transistor is turned off;
a potential level of an output signal of the output terminal increases; and
the seventh transistor is turned on and the eighth transistor is turned on.

4. The Schmitt trigger circuit according to claim 3, wherein, when the signal having a potential level below the reference voltage of the Schmitt trigger circuit is input to the input terminal, a potential level of the source of the fifth transistor is approximately the same as a potential level of the drain of the fifth transistor.

5. The Schmitt trigger circuit according to claim 4, wherein, when the potential level of the signal input to the input terminal is increased and kept below the reference voltage of the Schmitt trigger circuit, the potential level of the output signal of the output terminal remains approximately the same.

6. The Schmitt trigger circuit according to claim 2, wherein, when a signal having a potential level above a reference voltage of the Schmitt trigger circuit is input to the input terminal:
the first transistor is turned off, the second transistor is turned off, the fifth transistor is turned on, and the sixth transistor is turned on;
a potential level of an output signal of the output terminal is approximately 0 V; and
the third transistor is turned on and the fourth transistor is turned on.

7. The Schmitt trigger circuit according to claim 6, wherein, when the signal having a potential level above the reference voltage of the Schmitt trigger circuit is input to the input terminal, a potential level of the source of the second transistor is approximately the same as a potential level of the drain of the second transistor.

8. The Schmitt trigger circuit according to claim 7, wherein, when the potential level of the signal input to the input terminal is decreased and kept above the reference voltage of the Schmitt trigger circuit, the potential level of the output signal of the output terminal remains approximately the same.

9. The Schmitt trigger circuit according to claim 1, wherein the first transistor, the second transistor, the third transistor, and the fourth transistor are each a p-channel metal oxide semiconductor (PMOS) transistor, and wherein the fifth transistor, the sixth transistor, the seventh transistor, and the eighth transistor are each an n-channel metal oxide semiconductor (NMOS) transistor.

10. The Schmitt trigger circuit according to claim 1, wherein the fourth transistor is provided in plurality, wherein the plurality of fourth transistors are provided in series, wherein an initial transistor of the plurality of fourth transistors comprises a source connected to the drain of the third transistor, and wherein a last transistor of the plurality of fourth transistors comprises a drain connected to the ground terminal, and wherein each of the fourth transistors except the last transistor of the fourth transistors comprises a drain connected to a source of an adjacent fourth transistor, and wherein each transistor of the fourth transistors comprises a gate connected to the output terminal.

11. The Schmitt trigger circuit according to claim 10, wherein the second transistor has a threshold voltage capable of being adjusted by adding or removing a transistor from the plurality of fourth transistors.

12. The Schmitt trigger circuit according to claim 1, wherein the eighth transistor is provided in plurality, wherein the plurality of eighth transistors are provided in series, wherein an initial transistor of the plurality of eighth transistors comprises a source connected to the drain of the seventh transistor, and wherein a last transistor of the plurality of eighth transistors comprises a drain connected to the power terminal, and wherein each of the eighth transistors except the last transistor of the eighth transistors comprises a drain connected to a source of an adjacent eighth transistor, and wherein each transistor of the eighth transistors comprises a gate connected to the output terminal.

13. The Schmitt trigger circuit according to claim 12, wherein the fifth transistor has a threshold voltage capable of being adjusted by adding or removing a transistor from the plurality of eighth transistors.

14. The Schmitt trigger circuit according to claim 12, wherein the fourth transistor is provided in plurality, wherein the plurality of fourth transistors are provided in series, wherein an initial transistor of the plurality of fourth transistors comprises a source connected to the drain of the third transistor, and wherein a last transistor of the plurality of fourth transistors comprises a drain connected to the ground terminal, and wherein each of the fourth transistors except the last transistor of the fourth transistors comprises a drain connected to a source of an adjacent fourth transistor, and wherein each transistor of the fourth transistors comprises a gate connected to the output terminal.
